(19) United States
(12) Patent Application Publication
(10) Pub. No.: US 2012/0068579 A1
(43) Pub. Date: Mar. 22, 2012

(54) Method for Manufacturing a Piezoelectric Device and the Same

(75) Inventors: Ryoichi Ichikawa, Sayama-Shi (JP); Yoshiaki Amano, Sayama-Shi (JP); Kenji Kamezawa, Sayama-Shi (JP)

(73) Assignee: NIHON DEMPA KOGYO CO., LTD., Tokyo (JP)

(21) Appl. No.: 13/238,770

(22) Filed: Sep. 21, 2011

(30) Foreign Application Priority Data
Sep. 22, 2010 (JP) 2010-212089
Mar. 11, 2011 (JP) 2011-053848

(51) Int. Cl. H01L 41/04; H01L 41/22

(52) U.S. Cl. 310/367; 29/25.35

(57) ABSTRACT

The present disclosure provides a method for manufacturing piezoelectric devices by using a base wafer having through-holes manufactured in precise size. In the method for manufacturing a piezoelectric device comprises: a step of: forming an anticorrosive film (S121) on a first surface and on a second surface opposing the first surface of the base wafer made of a glass or a piezoelectric material; after forming a photoresist on the anticorrosive film and exposing, metal-etching the anticorrosive film (S121, S122) corresponding to the through-hole; after the metal-etching step, applying an etching solution onto the glass or the piezoelectric material and wet-etching (S123) the first surface and the second surface of the base wafer until before completely cutting through the glass or the piezoelectric material; and applying an abrasive from the second surface with the anticorrosive film remaining in place on the second surface, by sand-blasting method (S124).

### CROSS-REFERENCE TO RELATED APPLICATION

This application claims priority to and the benefit of Japan Patent Application No. 2010-212089, filed on Sep. 22, 2010 and Japan Patent Application No. 2011-053848, filed on Mar. 11, 2011, in the Japan Patent Office, the disclosures of which are incorporated herein by reference in their entirety.

### FIELD

The present disclosure pertains to methods for manufacturing a piezoelectric device in which the piezoelectric vibrating piece is mounted onto the package base formed on the base wafer. This disclosure also pertains to the piezoelectric device thereof.

### DESCRIPTION OF THE RELATED ART

The surface-mountable piezoelectric devices are preferred to be compatible with mass-production. Japan Unexamined Patent Publication No. 2001-267875 discloses a method of manufacturing piezoelectric devices by manufacturing a lid wafer and base wafer. In the manufacturing method disclosed in Japan Unexamined Patent Publication No. 2001-267875, through-holes are formed on the lid wafer or base wafer, and thin metal films of electrode patterns are formed on the through-holes.

However, the manufacturing method of piezoelectric devices in Japan Unexamined Patent Publication No. 2001-267875 only discloses the through-holes are formed by laser, wet-etching or sand-blasting, and does not disclose the difference between each method and the best-mode in each method in detail. As the piezoelectric device miniaturizes, the complexity forming an appropriate size of through-holes and electrodes on the through-holes is increasing.

It is therefore the purpose of the present disclosure to provide a method for manufacturing piezoelectric devices by using a base wafer having through-holes manufactured in appropriate size.

### SUMMARY

A first aspect of the present disclosure pertains to a method for manufacturing piezoelectric devices. In its first aspect, the piezoelectric device having a piezoelectric vibrating piece and a package base is manufactured, by using a package base and a base wafer having a plurality of through-holes formed in periphery of the package base. The method for manufacturing the piezoelectric device comprises: a step of forming an anticorrosive film on a first surface and on a second surface opposing the first surface of the base wafer made of a glass or a piezoelectric material; a step of exposing, metal-etching the anticorrosive film corresponding to the through-hole, after the forming step; a step of applying an etching solution to the glass or the piezoelectric material and wet-etching the first surface and the second surface of the base wafer before completely cutting through the glass or the piezoelectric material, after the metal-etching step; and a step of sand-blasting an abrasive from the second surface side, with the anticorrosive film remaining in place on the second surface.

A second aspect of the present disclosure pertains to a method for manufacturing piezoelectric devices. In its second aspect, the method includes sand-blasting the abrasive from the first surface side, with the anticorrosive film remaining in place on the first surface.

A third aspect of the present disclosure pertains to a method for manufacturing piezoelectric devices. The method further comprises, after the sand-blasting step, a removal step of removing the anticorrosive film; and a step of forming an external electrode on the second surface for mounting and forming a side surface electrode on respective through-holes, after the removal step.

A fourth aspect of the present disclosure pertains to a method for manufacturing piezoelectric devices. In its fourth aspect, the package base has a rectangular shape with four sides, when viewed from the second surface, and respective through-holes have a circular profile, formed on opposing corners of the package base.

A fifth aspect of the present disclosure pertains to a method for manufacturing piezoelectric devices. In its fifth aspect, the package base has a rectangular shape with four sides, when viewed from the second surface, and respective through-holes have a rounded-rectangular profile, formed on opposing sides along the package base.

A sixth aspect of the present disclosure pertains to piezoelectric devices. In its sixth aspect, the piezoelectric device includes a piezoelectric vibrating piece disposed inside a cavity formed by a package lid and a package base. The package base comprises a first surface having a pair of external electrodes, a second surface opposing the first surface and a pair of connecting electrodes on the second surface for connecting to the external electrodes through a side surface formed between the first surface and the second surface. As viewed in a cross-section, the side surface between the first surface and a second surface comprises a first region defined as a region between the first surface and a center of the side surface, a second region defined as a region between the second surface and the center of the side surface, and a protruding region formed in the center of the side surface and protruding outward.

A seventh aspect of the present disclosure pertains to piezoelectric devices. In its seventh aspect, the second surface is an uneven surface formed by sand-blasting.

An eighth aspect of the present disclosure pertains to piezoelectric devices. In its eighth aspect, the first surface is an uneven surface formed by sand-blasting.

According to the present disclosure, the piezoelectric devices having high impact resistance are manufactured by individual base wafer, thus reducing the manufacturing cost.

### BRIEF DESCRIPTION OF THE DRAWINGS

FIG. 1 is an exploded perspective view of the first quartz-crystal vibrating device 100 in the first embodiment.

FIG. 2 is a cross-sectional view of the FIG. 1 taken along A-A line.

FIG. 3 is a flow-chart of steps of the first embodiment of a method for manufacturing the first quartz-crystal vibrating device 100.

FIG. 4 is a plan view of the first quartz-crystal wafer 10W.

FIG. 5 is a plan view of the first lid wafer 11W.

FIG. 6A to FIG. 6F depicts the results of respective steps S12 of manufacturing a package base 12. FIGS. 6A to FIG. 6F are cross-sectional views of the base wafer 12W taken along A-A line of FIG. 1, which corresponds to each step on the flow-chart.

FIG. 7 is a plan view of the base wafer 12W.

FIG. 8 is a cross-sectional view of the first quartz-crystal vibrating device 100′ of an alternative to the first embodiment, taken along the A-A line of FIG. 1.

FIG. 9A to FIG. 9C depicts the results of respective steps S12′ of manufacturing a package base 12′. FIG. 9A to FIG. 9C are cross-sectional views of the base wafer 12W taken along A-A line of FIG. 1, which corresponds to each step on the flow-chart.

FIG. 10 is an exploded perspective view of the second quartz-crystal vibrating device 200 of the second embodiment, in which the low-melting-point glass LG is omitted from the drawing.

FIG. 11 is cross-sectional view of the FIG. 10 taken along B-B line of FIG. 10.

FIG. 12A to FIG. 12F depicts the results of respective steps T20 of manufacturing a quartz-crystal frame 20. FIG. 12A to FIG. 12F are cross-sectional views of the quartz-crystal wafer 20W taken along B-B line of FIG. 10, which corresponds to each step on the flow-chart.

FIG. 13 is a plan view of the quartz-crystal wafer 20W.

FIG. 14 is a plan view of the base wafer 22W.

### DETAILED DESCRIPTION

In the first and second embodiments described below, an AT-cut quartz-crystal vibrating piece is used as the piezoelectric vibrating piece. An AT-cut quartz-crystal vibrating piece has a principal surface (in the YZ plane) that is tilted by 35° 15′ about the Y-axis of the crystal coordinate system (XYZ) in the direction of the Y-axis from the Z-axis around the X-axis. Thus, new axes tilted with respect to the axial directions of the quartz-crystal vibrating piece are denoted as the Y′-axis and Z′-axis, respectively. Therefore, in the first and second embodiments, the longitudinal direction of the quartz-crystal vibrating devices are referred as the X-axis direction, the height direction of the vibrating devices are referred as the Y′-axis direction, and the direction normal to the X-axis and Y′-axis directions are referred as the Z′-axis direction, respectively.

### First Embodiment

### <Overall Configuration of the First Quartz-Crystal Vibrating Device 100>

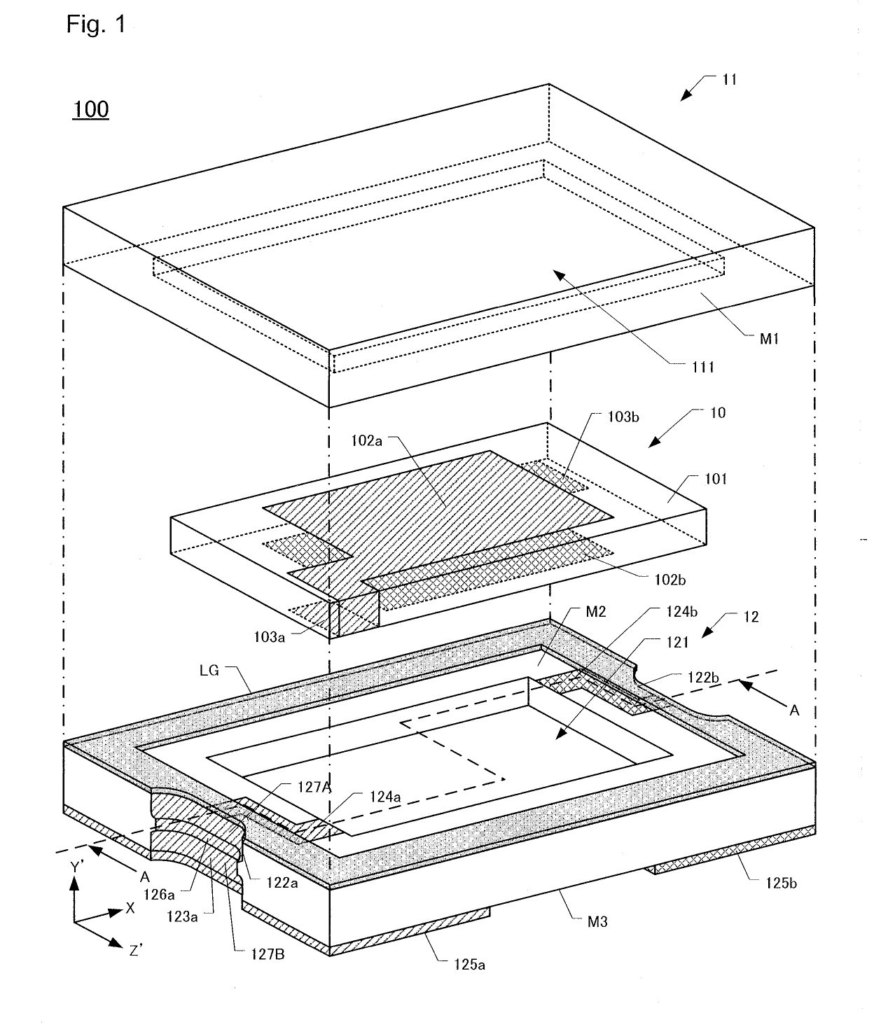

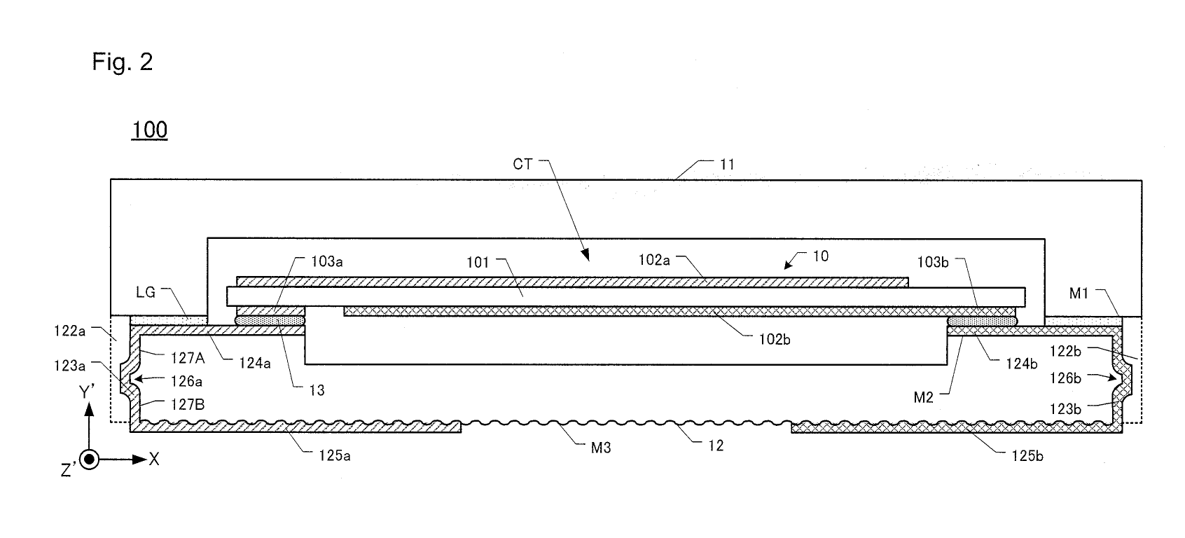

The general configuration of a first quartz-crystal vibrating device 100 is explained using FIGS. 1 and 2 as references. FIG. 1 is an exploded perspective view of the first quartz-crystal vibrating device 100 and FIG. 2 is a cross-sectional view of FIG. 1 taken along A-A line. In FIG. 1, a low-melting-point glass LG, which is used as a sealing material, is drawn as a transparent material, so that the entire connecting electrodes 124a and 124b can be viewed.

As shown in FIGS. 1 and 2, a first quartz-crystal vibrating device 100 comprises a package lid 11 defining a lid recess 111 configured as a concavity in the inner main surface of the package lid 11, a package base 12 defining a base recess 121 configured as a concavity in the inner main surface of the package base 12, and a quartz-crystal vibrating piece 10 mounted on the package base 12.

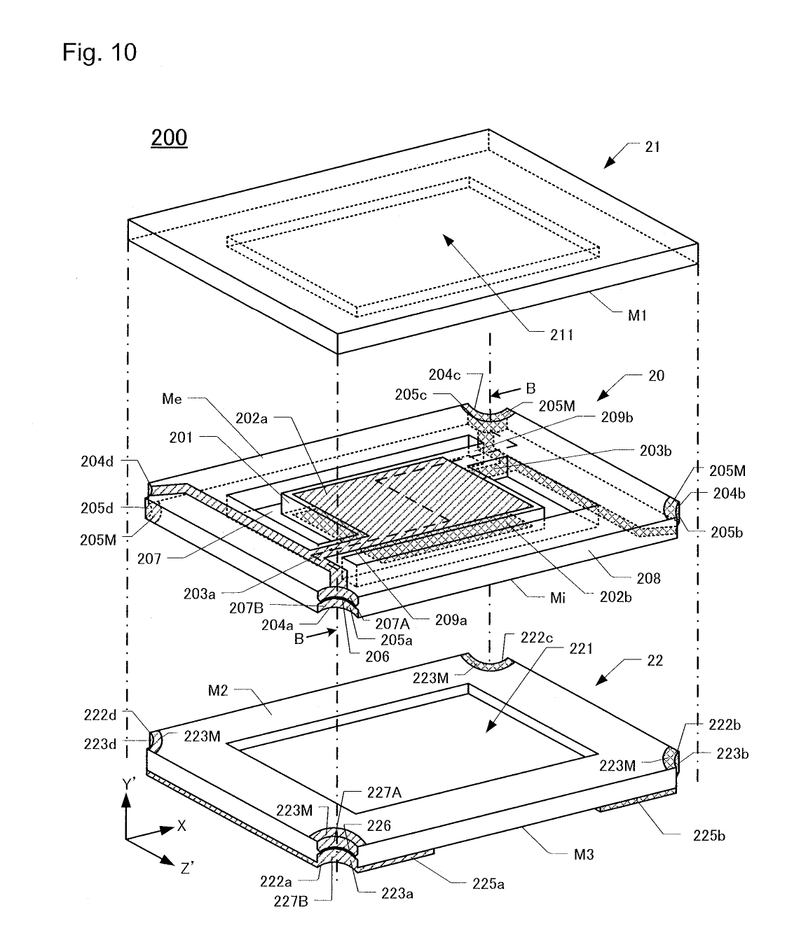

The quartz-crystal vibrating piece 10 is constituted of the AT-cut quartz-crystal piece 101, and excitation electrodes 102a and 102b are situated opposite each other essentially at the center of both principal surfaces of the quartz-crystal piece 101. An extraction electrode 103a, which is extended to the bottom surface (−Y′-axis side surface) and toward −X-axis side, is connected to the excitation electrode 102a. And an extraction electrode 103b, which is extended to the bottom surface (−Y′-axis side surface) and toward +X-axis side, is connected to the excitation electrode 102b. The quartz-crystal vibrating piece 10 can be mesa-type or inverted-mesa type. A pair of L-shaped airspaces 207 can be formed surrounding the excitation electrodes 102a and 102b of the quartz-crystal vibrating piece 10, as shown in FIG. 10.

The excitation electrodes 102a and 102b, and extraction electrodes 103a and 103b, comprise a foundation layer of chromium with an overlying layer of gold. An exemplary thickness of the chromium layer is in the range of 0.05 μm to 0.1 μm, and an exemplary thickness of the gold layer is in the range of 0.2 μm to 2 μm.

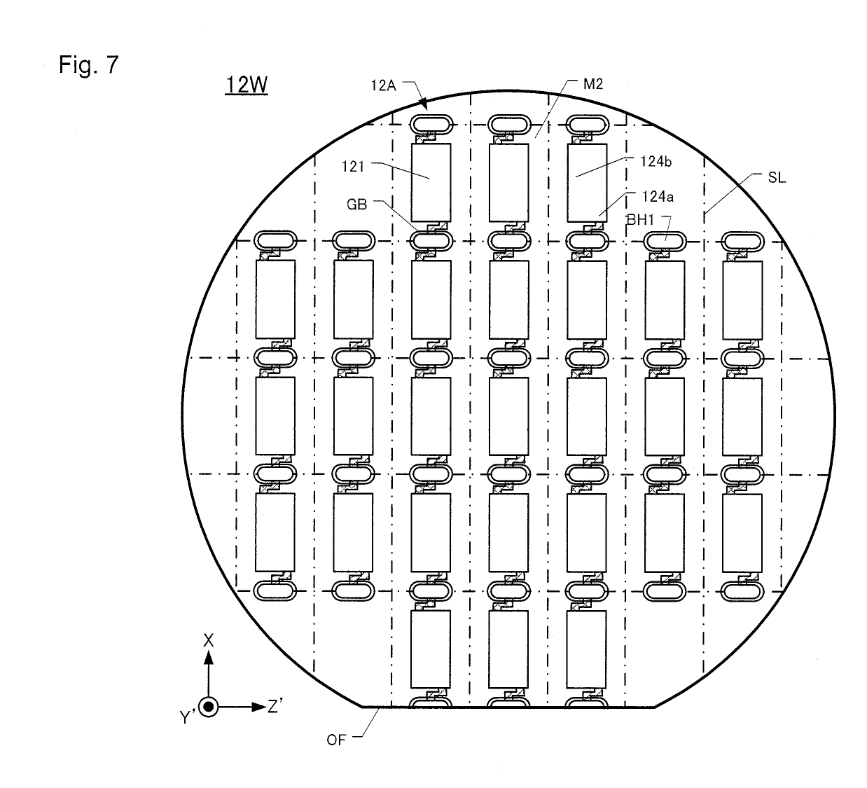

The package base 12 comprises a second peripheral surface M2 surrounding the base recess 121, on the first surface (+Y′-side surface). Respective base castellations 122a and 122b are formed on both ends of the package base 12 in respective X-axis directions, which is formed simultaneously with formation of the base through-holes BH1 (refer to FIG. 7) and extend in the Z′-axis direction.

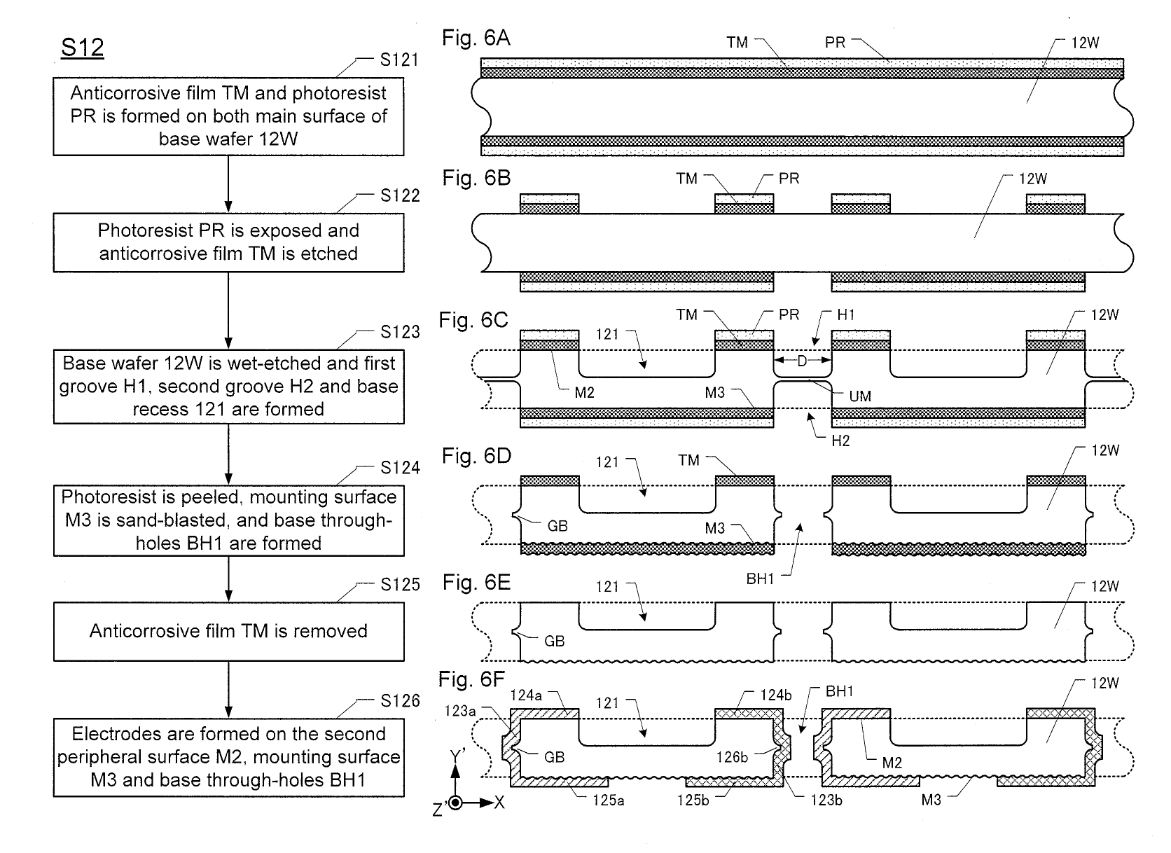

On the base castellations 122a and 122b, respective protruding portions 126a and 126b are disposed in the center (in the thickness direction Y′) of the end surface and protruding outward in the X-axis direction. Thus, the base castellations 122a and 122b include a first region 127A of a curved surface extending from the protruding portions 126a and 126b to the respective second peripheral surface M2, and a second region 127B of a curved surface from the protruding portions 126a and 126b to the respective mounting surface M3. The protruding portions 126a and 126b are the convex portions GB (refer to FIG. 6) which are formed simultaneously with the package base. The mounting surface M3 is a mounting surface of the quartz-crystal vibrating device, and an uneven surface of small concavities and convexities are simultaneously formed.

Respective base side surface electrodes 123a and 123b are formed on the base castellations 122a, 122b. A connecting electrode 124a, situated on the second peripheral surface M2 and extending in the −X-axis direction, is electrically connected to the respective base side surface electrode 123a. Similarly, a connecting electrode 124b, situated on the second peripheral surface M2 and extending in the +X-axis direction on the package base 12, is electrically connected to the respective base side surface electrode 123b. The package base 12 also comprises a pair of external electrodes 125a, 125b, which are electrically connected to respective base side surface electrodes 123a and 123b. The base side surface electrodes, the connecting electrodes and the extraction electrodes are constituted in a same manner as the excitation electrodes and extraction electrodes in the quartz-crystal vibrating piece 10.

In the first quartz-crystal vibrating device 100, a length of the quartz-crystal vibrating piece 10 in the X-axis direction is longer than a length of a base recess 121 in the X-axis direction. Therefore, by mounting the quartz-crystal vibrating piece 10 onto the package base 12 using electrically conductive adhesive 13, both edges of the quartz-crystal vibrating piece 10 in the X-axis direction are mounted onto the second peripheral surface M2 of the package base 12, as shown in FIG. 2. Here, each of the extraction electrodes 103a and 103b are electrically connected to the respective connecting electrodes 124a and 124b. Thus, the external electrodes 125a and 125b are electrically connected to the respective excitation electrodes 102a and 102b via the respective base side surface electrodes 123a and 123b and respective connecting electrodes 124a and 124b, electrically conductive adhesive 13, and extraction electrodes 103a and 103b. Whenever an alternating voltage is applied across the external electrodes 125a, 125b, the quartz-crystal vibrating device 10 exhibits thickness-shear vibration.

The package lid 11 comprises a lid recess 111, having a larger area in the XZ′-plane surface than the corresponding base recess 121 of the package base 12, and a first peripheral surface M1 formed on the periphery of the lid recess 111. When the first peripheral surface M1 of the package lid 11 and the second peripheral surface M2 of the package base 12 are bonded, a cavity CT for storing the quartz-crystal vibrating piece 10 is formed. The cavity CT is filled with an inert-gas or is under a vacuum.

The first peripheral surface M1 of the package lid 11 and the second peripheral surface M2 are bonded using a sealing material (non electrically conductive adhesive) of, for example, a low-melting-point glass LG. Low-melting-point glass LG is a lead-free vanadium-based glass having an adhesive component that melts at 350° C. to 400° C. Vanadium-based glass can be formulated as a paste mixed with binder and solvent. Vanadium-based glass bonds to various materials by melting and solidification. This vanadium-based glass forms a highly reliable air-tight seal and resists water and humidity. Also, since the coefficient of thermal expansion of low-melting-point glass can be controlled effectively by controlling its glass structure, the low-melting-point glass can adjust to various coefficients of thermal expansion.

The length of the lid recess 111 of the package lid 11 in the X-axis direction is longer than length of the quartz-crystal vibrating piece 10 in the X-axis direction and the base recess 121 in the X-axis direction. As shown in FIGS. 1 and 2, the low-melting-point glass LG is disposed along the outer edge of the second peripheral surface M2 of the package base 12 (width of 300 μm) and bonds the package lid 11 and the package base 12.

Also, although the quartz-crystal vibrating piece 10 is illustrated mounted onto the second peripheral surface M2 of the package base 12, the quartz-crystal vibrating piece 10 can alternatively be stored within the base recess 121. Here, the connecting electrodes should be extended to the bottom surface of the base recess 121 via the base castellations 122a and 122b and the second peripheral surface M2. In such a configuration, the package lid can be a planar surface without a lid recess.

Furthermore, although the extraction electrodes 103a, 103b for electrically connecting to the connecting electrodes 124a 124b are illustrated on each side of bottom surface (−Y′-axis side surface) of the quartz-crystal vibrating piece 10 in X-axis direction, Both of them can be formed on the same end of the quartz-crystal vibrating piece in the X-axis direction. In this case, one connecting electrode (+X-axis side, for example), should go through the second peripheral surface M2 or the base recess 121 and extend to the other side (−X-axis side, for example).

### <Manufacturing Method of the First Quartz-Crystal Vibrating Device 100>

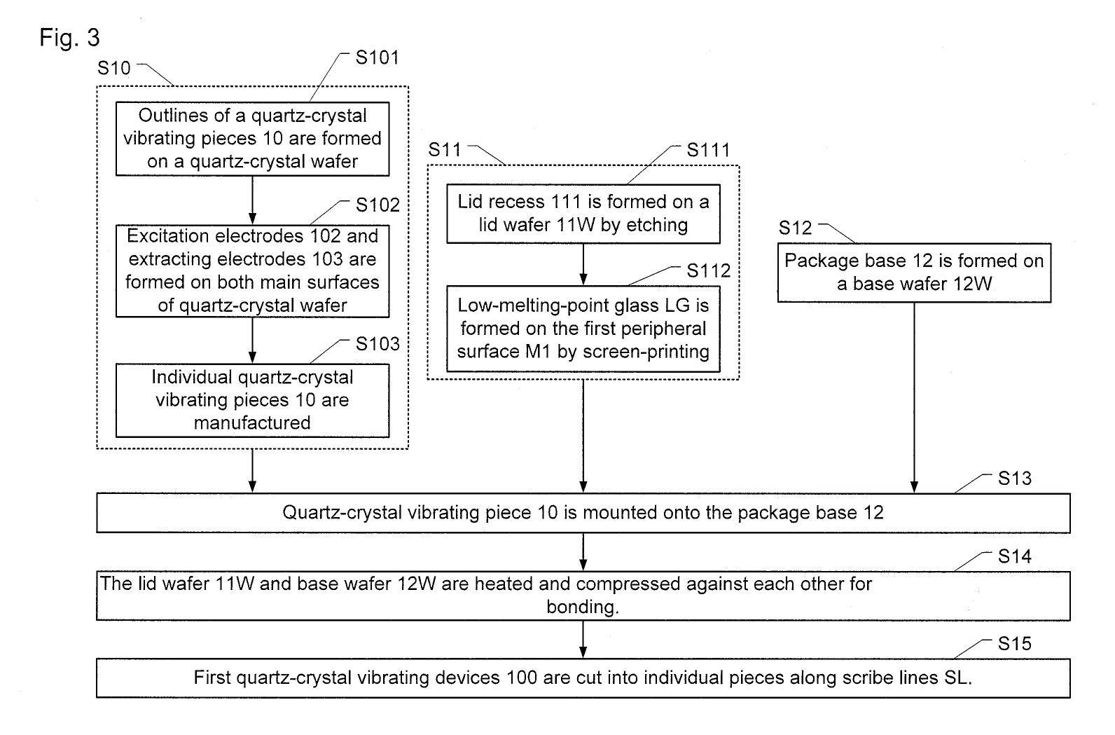

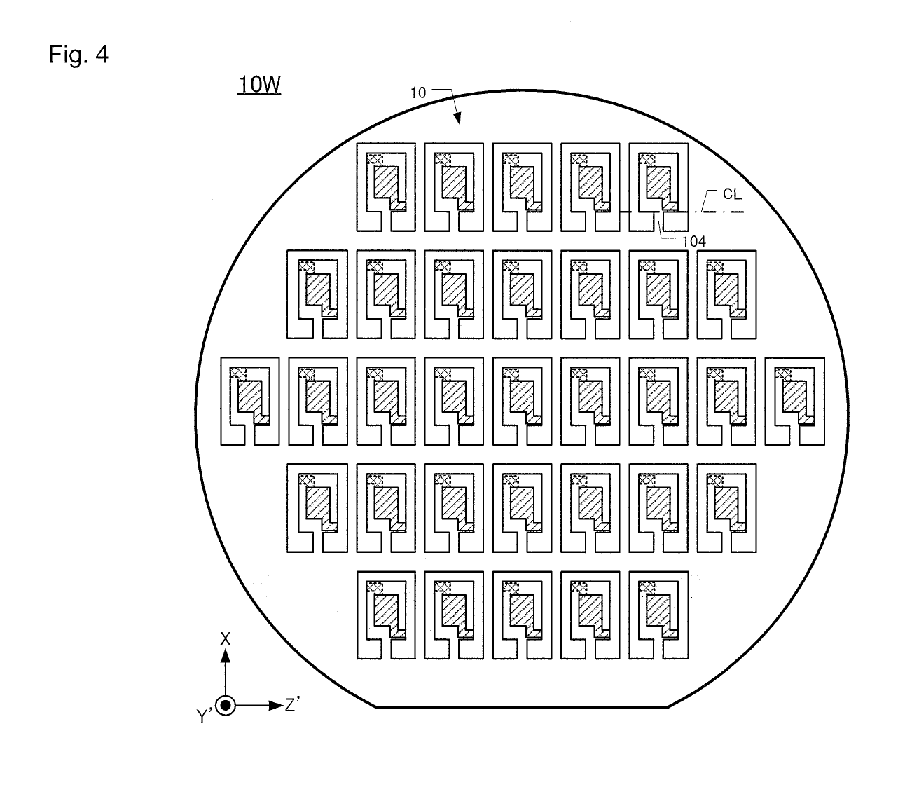

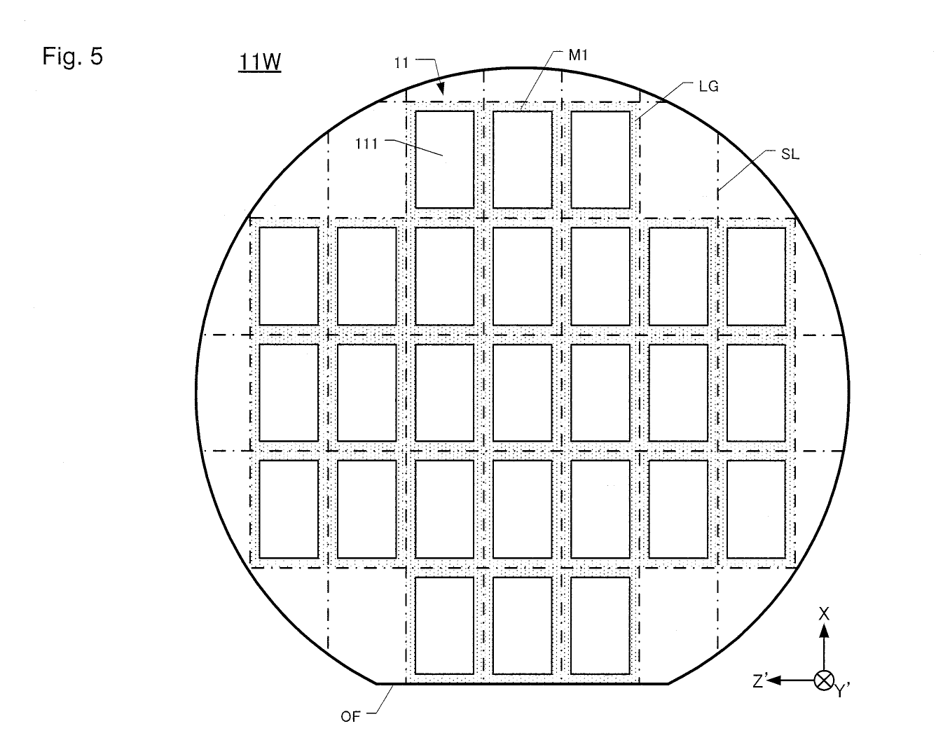

FIG. 3 is a flow-chart of a method for manufacturing the first quartz-crystal vibrating device 100. In FIG. 3, the protocol S10 for manufacturing the quartz-crystal vibrating piece 10, the protocol S11 for manufacturing the package lid 11 and the protocol 12 for manufacturing the package base 12 can be carried out in parallel. FIG. 4 is a plan view of the quartz-crystal wafer 10W, and FIG. 5 is a plan view of the lid wafer 11W. FIG. 6A to FIG. 6F depicts the results of respective steps S12 of manufacturing a package base 12, and FIG. 7 is a plan view of the base wafer 12W. FIG. 6A to FIG. 6F are cross-sectional views of the base wafer 12W taken along A-A line of FIG. 1, which corresponds to each step on the flow-chart.

In protocol S10, the quartz-crystal vibrating piece 10 is manufactured. The protocol S10 includes steps S101 to S103.

In step S101 (see FIG. 4) the outlines of a plurality of quartz-crystal vibrating pieces 10 are formed on a planar quartz-crystal wafer 10W by etching. Each quartz-crystal vibrating piece 10 is connected to the quartz-crystal wafer 10W by a respective joining portion 104.

In step S102 a layer of chromium is formed, followed by formation of an overlying layer of gold, on both main surfaces and side surfaces of the entire quartz-crystal wafer 10W by sputtering or vacuum-deposition. Then, a photoresist is applied uniformly on the surface of the metal layer. Using an exposure tool (not shown), the outlines of the excitation electrodes and of the extraction electrodes are exposed onto the crystal wafer 10W. Next, regions of the metal layer are denuded by etching. As shown in FIG. 4, the excitation electrodes 102a and 102b, and extraction electrodes 103a and 103b are formed on both main surfaces and side surfaces of the quartz-crystal wafer 10W (refer to FIG. 1).

In step S103 the quartz-crystal vibrating pieces 10 are cut to separate individual devices. During cutting, cuts are made along cut lines CL (denoted by dot-dash lines in FIG. 4) using a dicing unit such as a laser beam or dicing saw.

In protocol S10, although a plurality of quartz-crystal vibrating pieces 10 are simultaneously formed on one piece of quartz-crystal wafer 10W, individual quartz-crystal piece can be polished, etched or provided with electrodes.

In protocol S11, a package lid 11 is manufactured. Protocol S11 includes steps S111 and S112.

In step S111, as shown in FIG. 5 several hundreds to several thousands of lid recesses 111 are formed on a main surface of a lid wafer 11W, a circular, uniformly planar plate of quartz-crystal material. The lid recesses 111 are formed in the lid wafer 11W by etching or mechanical processing, leaving the first peripheral surfaces M1 around the lid recesses 111.

In step S112 low-melting point glass LG is printed on the first peripheral surface M1 of the lid wafer 11W by screen-printing. A film of low-melting-point glass is formed on the first peripheral surface M1 of the lid wafer 11W and preliminarily cured. Although the low-melting-point glass LG is formed on the package lid 11 in this embodiment, it can be formed on the base wafer 12.

In protocol S12, the package base 12 is manufactured. Thickness of the base wafer 12W is between 300 μm to 700 μm. As shown in FIG. 6, protocol S12 includes steps S121 to S126.

In step S121, as shown in FIG. 6A, an anticorrosive film TM is applied on both main surfaces of the base wafer 12W, a uniformly thick planar plate of quartz-crystal material, followed by overlaying photoresist PR. A metal film of an anticorrosive film is formed by sputtering or vacuum-deposition. For example, a foundation layer of nickel (Ni), chromium (Cr), titanium (Ti) or nickel tungsten (NiW) is formed on a single quartz-crystal base wafer 12W, and overlaying gold (Au) or silver (Ag) is applied on top of the foundation layer. In the first embodiment, a metal layer having a chromium layer and overlaying gold layer is used as the anticorrosive film TM. An exemplary thickness of the chromium layer is 100 angstrom, and the gold layer is 1,000 angstrom, for example. Next, a photoresist PR is applied uniformly on top of the anticorrosive film TM by using methods such as spin-coating method.

In step S122 (shown in FIG. 6B), using an exposure tool (not shown), the outline patterns of the package base 12 drawn on the photomask (not shown) are exposed onto the photoresist PR on both main surfaces the base wafer 12W. The denuded photoresist PR is removed by developing. Next, the gold layer of the anticorrosive film exposed from the photoresist PR is etched using aqueous solutions of, for example, iodine and potassium iodide. The chromium layer, exposed by removing the gold layer is etched using aqueous solutions of, for example, diammonium serium nitrate and acetic acid. Such process removes the anticorrosive film TM from the photoresist PR.

In step S123, as shown in FIG. 6C, both main surfaces of the base wafer 12W, exposed by removal of the anticorrosive film TM and the photoresist PR, are wet-etched using the aqueous solutions of, for example, hydrofluoric acid. Thus, several hundreds to several thousands of the base recesses 121 are formed, all having a depth of 100 μm to 300 μm. Also, the second peripheral surfaces M2 are formed in periphery of the base recess 121. The first grooves H1, the second grooves H2 and bottom surfaces UM are formed on both sides of each base recesses 121 in both X-axis directions, each groove is formed from the second peripheral surface M2 or the mounting surface M3 and extend toward bottom surfaces UM by a depth of 100 μm to 300 μm. Since the base recesses 121 and the first grooves H1 are formed at the same time, the base recesses 121 and the first grooves H1 have the same depth. The dimension D of the first groove H1 and the second groove H2 in the X-axis direction is approximately 200 μm to 400 μm.

Depth and the width dimension D on each first groove H1 and second groove H2 are protected from excess removal of material by controlling the duration of wet-etching, and by adjusting the concentration and temperature of the hydrofluoric acid solution. A small hole can cut through a part of the bottom surface UM between the first groove H1 and second groove H2. However, if the grooves are wet-etched until the bottom surface UM disappears completely, the width dimension D becomes greater, thus narrowing the width of the second peripheral surface M2. Therefore, while wet-etching the bottom surface UM, the entire bottom surface UM remains or a small hole is formed on a part of the bottom surface UM.

If the glass is wet-etched until the bottom surface disappears, a sealing surface of sufficient width cannot be obtained, since the glass is isotropically-etched. Therefore, the wet-etching is limited to the minimum processing necessary to form the base recesses 121 and the grooves H1, H2 are completed by sand-blasting. By using sand-blasting to open the grooves H1, H2, the width dimension D of sealing surface M2 is preserved and the shape of the through-holes is defined, and thus allowing the formation of electrodes on the base castellations 122a and 122b.

In step S124, as shown in FIG. 6D, the photoresist PR is peeled, and an abrasive is sand-blasted onto the mounting surface M3. Thus, the bottom surfaces UM between the first groove H1 and second groove H2 are sand-blasted and then the rounded-rectangular base through-holes BH1 are formed, which extend through from the second peripheral surface M2 to the mounting surface M3 on the base wafer 12W (refer to FIG. 7). By sand-blasting after the wet-etching, the base through-holes BH1 are formed in an appropriate size, and thus makes the wet etching processing duration shorter. When a base through-hole BH1 is divided in half, it forms base castellations 122a and 122b (refer to FIGS. 1 and 2). Also, the convex portions GB are formed (refer to FIG. 7) on about center in the thickness direction of base wafer 12W, which is protruding toward the inner side of the base through-holes BH1. When a convex portion GB is divided in half, it forms protruding portions 126a and 126b (refer to FIGS. 1 and 2).

Further, when sand-blasting is applied onto the entire mounting surface M3 with the anticorrosive film TM formed, an uneven surface of small concavities and convexities are formed on the anticorrosive TM as well as on the first surface of base wafer 12W, thus making surfaces of the mounting surface M3 of the base wafer 12W uneven. If an abrasive is directly sand-blasted onto the front surface of the base wafer 12W, small concavities and convexities are formed on the first surface of the base wafer 12W; however, such small and sharp concavities and convexities are likely to cause micro-cracks. Such micro-cracks weaken the hardness of the package base 12. On the other hand, if the abrasives were sand-blasted onto the surface with the anticorrosive films TM formed, it forms smooth concavities and convexities, thus also prevents micro-cracks.

In step S125, as shown in FIG. 6E, the anticorrosive film TM is removed by etching.

In step S126, as shown in FIG. 6F, the external electrodes 125a and 125b are formed on the mounting surface M3 of the package base 12 in both X-axis directions by sputtering and etching method of step S102. Here, an uneven surface of small concavities and convexities formed on the front surface of the base wafer 12W improves the adhesiveness of chromium to the base wafer 12W whenever the external electrodes 125a and 125b are formed. At the same time, the base side surface electrodes 123a and 123b are formed on the base through-holes BH1, and the connecting electrodes 124a and 124b are formed on the second peripheral surface M2 (refer to FIGS. 1, 2 and 7).

In step S13, the quartz-crystal vibrating piece 10 manufactured in protocol S10 is mounted onto the second peripheral surface M2 of the package base 12 using the electrically conductive adhesive 13. Here, the quartz-crystal vibrating piece 10 is mounted onto the second peripheral surface M2 of the package base 12, so as to align the extraction electrodes 103a and 103b on the quartz-crystal vibrating piece 10 and the connecting electrodes 124a and 124b on the second peripheral surface M2 of the package base 12 (refer to FIG. 2).

In step S14, the low-melting-point glass LG is heated and the lid wafer 11W and base wafer 12W are compressed against each other. Thus the lid wafer 11W and the base wafer 12W are bonded using the low-melting-point glass LG.

In step S15, the bonded-together lid wafer 11W and base wafer 12W is cut up to separate individual quartz-crystal vibrating devices 100 from the wafer and from each other. This cutting is performed by cutting along scribe lines SL, denoted by dot-dash lines in FIGS. 5 and 7, using a dicing unit such as a laser beam or a dicing saw. Thus, several hundreds to several thousands of quartz-crystal piezoelectric vibrating devices 100 are produced.

### Alternative to the First Embodiment

### <Overall Configuration of the First Quartz-Crystal Vibrating Device 100′>

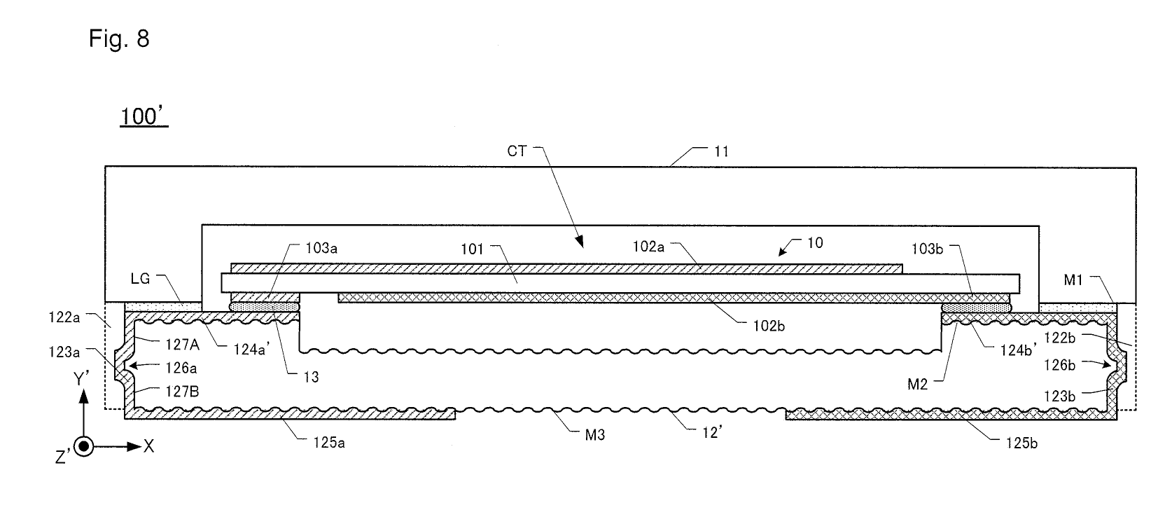

This alternative configuration of the first embodiment of a piezoelectric vibrating device 100′ is described with references to FIG. 8. FIG. 8 is a cross-sectional view of the first quartz-crystal vibrating device 100′, which corresponds to the A-A cross section in FIG. 1.

As shown in FIG. 8, the first quartz-crystal vibrating device 100′ comprises a quartz-crystal vibrating piece 10, a package lid 11 and a package base 12′. An uneven surface of small concavities and convexities are formed on surfaces of the second peripheral surface M2, mounting surface M3 and bottom surface of the base recess 121 of the package base 12′.

According to this configuration, adhesiveness of chromium against the package base 12′ increases whenever the external electrodes 125a and 125b, and connecting electrodes 124a′ and 124b′ are formed on the package base 12′. Furthermore, such configuration increases the adhesiveness of the low-melting-point glass LG and the package base 12′ whenever the package lid 11 and package base 12′ are bonded using the low-melting-point glass LG.

### <Manufacturing Method of the First Quartz-Crystal Vibrating Device 100′>

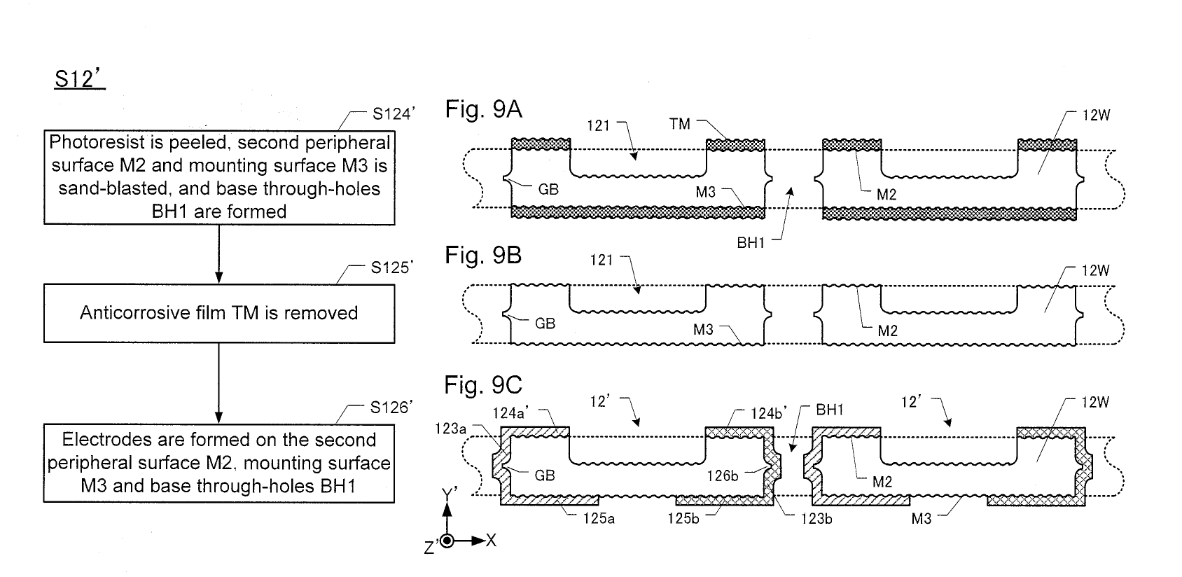

Manufacturing method of the first quartz-crystal vibrating device 100′ follows the same manufacturing method as explained in the flow-chart in FIGS. 3 and 6 in the first embodiment, and differs from the steps of FIG. 6 in the previous embodiment as explained below. FIG. 9A to FIG. 9C depicts the results of respective steps S12′ of manufacturing a package base 12′. FIG. 9A to FIG. 9C are cross-sectional views of the base wafer 12W taken along A-A line, which corresponds to each step on the flow-chart.

In step S124′, as shown in FIG. 9A, an abrasive is applied onto the second peripheral surface M2 and the entire surface of the mounting surface M3 by sand-blasting, with the photoresist PR peeled. Thus, the rounded-rectangular base through-holes BH1 are formed, which extend through from the second peripheral surface M2 to the mounting surface M3 on the base wafer 12W (refer to FIG. 7).

Further, when a sand-blasting is applied onto the second peripheral surface M2 and the entire mounting surface M3 where the anticorrosive film TM is formed, an uneven surface of small concavities and convexities are formed on the first surface of the anticorrosive film TM and base wafer 12W, thus making surfaces of the second peripheral surface M2 and the mounting surface M3 of the base wafer 12W uneven.

In step S125′, as shown in FIG. 9B, the anticorrosive films TM are removed by etching.

In step S126′, as shown in FIG. 9C, the external electrodes 125a and 125b are formed on the mounting surface M3 of the package base 12′ by sputtering and etching method, and the connecting electrodes 124a′ and 124b′ are formed on the second peripheral surface M2. Here, since the first surface of the base wafer 12W is an uneven surface having small concavities and convexities, and adhesiveness of chromium to the base wafer 12W increases whenever the external electrodes 125a and 125b, and connecting electrodes 124a′ and 124b′ are formed. Similarly, the base side surface electrodes 123a and 123b are formed on the base through-hole BH1.

Also, although not described in figure, the second peripheral surface M2 of the base wafer 12W has an uneven surface, and this increases adhesion between the low-melting-point glass LG and the base wafer 12W when bonding the lid wafer 11W and base wafer 12W using the low-melting-point glass LG in step S14 in FIG. 3.

### Second Embodiment

### <Overall Configuration of the Second Quartz-Crystal Vibrating Device 200>

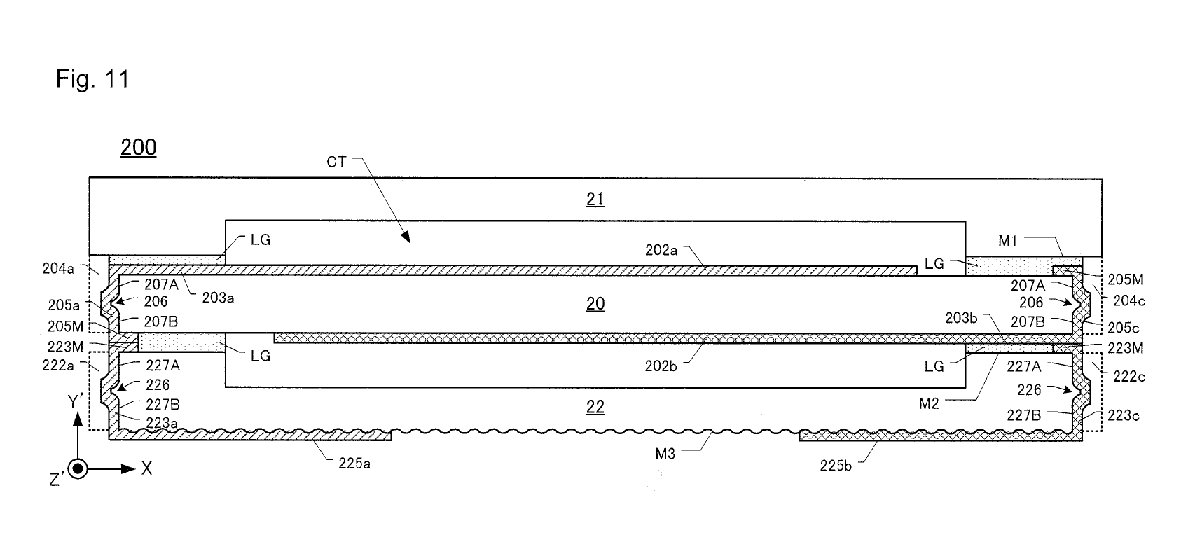

Overall configuration of the second quartz-crystal vibrating device 200 is explained using FIGS. 10 and 11 as references. FIG. 10 is an exploded perspective view of the second quartz-crystal vibrating device 200 in the second embodiment, and FIG. 11 is a cross-sectional view of FIG. 10 taken along B-B line of FIG. 10. In FIG. 10, the low-melting-point glasses LGs, formed between a package lid 21 and a quartz-crystal frame 20 and between a quartz-crystal frame 20 and a package base 20, are omitted from the drawing.

As shown in FIGS. 10 and 11, a second quartz-crystal vibrating device 200 comprises a package lid 21 defining a lid recess 211 configured as a concavity in the inner main surface of the package lid 21, a package base 22 defining a base recess 221 configured as a concavity in the inner main surface of the package base 22, and a quartz-crystal frame 20 sandwiched between the package lid 21 and the package base 22.

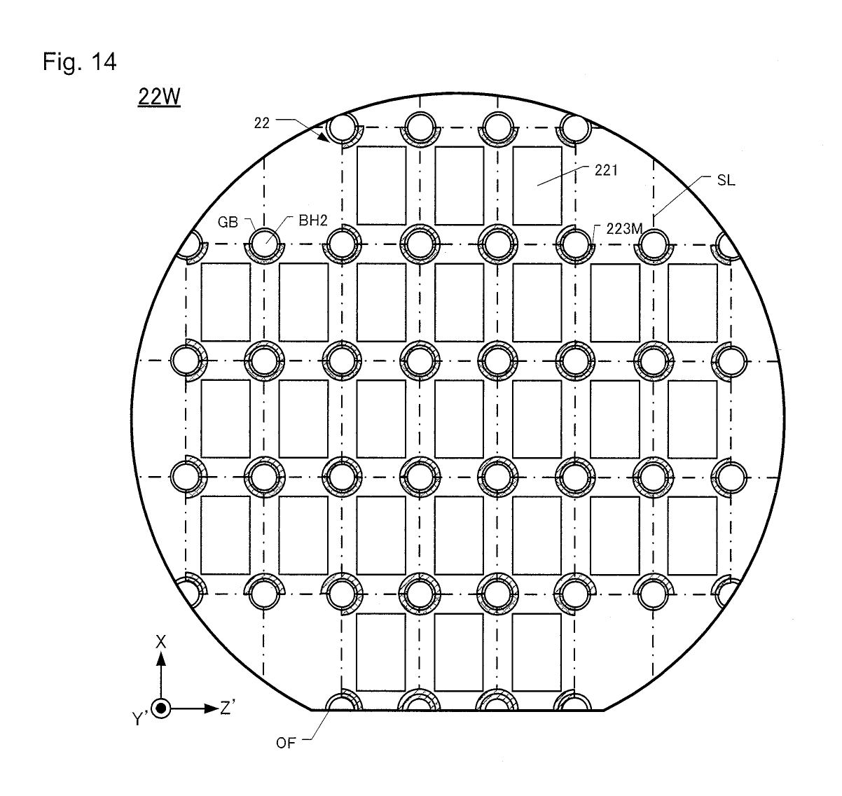

The package base 22 is made of a glass or quartz-crystal material, and a second peripheral surface M2 is formed on the first surface (+Y′-axis side surface), on the periphery of the base recess 221 of the package base 22. Quarter-rounded base castellations 222a to 222d are formed on each corner of the package base 22, which castellations were formed simultaneously with formation of the base through-holes BH2 (refer to FIG. 14) and extend in the XZ′-plane.

Respective protruding portions 226, formed of the convex portion GB (refer to FIG. 14), are formed about the center in the Y′-axis direction on the base castellations 222a and 222d. Thus, the base castellations 222a and 222d includes a first region 227A having a curved surface from the protruding portions 226 to the respective second peripheral surface M2, and a second region 227B having a curved surface from the protruding portions 226 to the respective mounting surface M3.

On the package base 22, respective base side surface electrodes 223a to 223d are formed on the base castellations 222a to 222d. A pair of external electrodes 225a and 225b is situated on each side of the mounting surface in the X-axis direction. One end of the base side surface electrode 223a and 223d is connected to the external electrode 225a, and the other end of the base side surface electrode 223b and 223c is connected to the external electrode 225b. Also, it is preferred that the other ends of the base side surface electrodes 223a to 223d extend toward the second peripheral surface M2 of the package base 22 and form a connecting pad 223M. The connecting pad 223M is ensured to be electrically connected to the quartz-crystal side surface electrodes 205a to 205d, which will be explained hereafter.

The quartz-crystal frame 20 is constituted of an AT-cut quartz-crystal material, bonded to the second peripheral surface M2 of the package base 22, and has a first surface Me on the +Y′-axis side and a second surface Mi on the −Y′-axis side. The quartz-crystal frame 20 is constituted of a quartz-crystal vibrating portion 201 and an outer frame 208 surrounding the quartz-crystal vibrating portion 201. A pair of L-shaped gaps 207, which cuts through from the first surface Me to the second surface Mi, is formed between the quartz-crystal vibrating portion 201 and the outer frame 208. A portion between two gaps 207 forms joining portions 209a and 209b, which connect the quartz-crystal vibrating portion 201 and the outer frame 208. On the first surface Me and the second surface Mi of the quartz-crystal vibrating portion 201, respective excitation electrodes 202a and 202b are formed, and on the joining portions 209a, 209b and each surface of the outer frame 208, respective extraction electrodes 203a and 203b are formed, which are electrically connected to the respective excitation electrodes 202a and 202b. Furthermore, on each corner of the quartz-crystal frame 20, respective quartz-crystal castellations 204a to 204d are formed on the quartz-crystal through-holes CH.

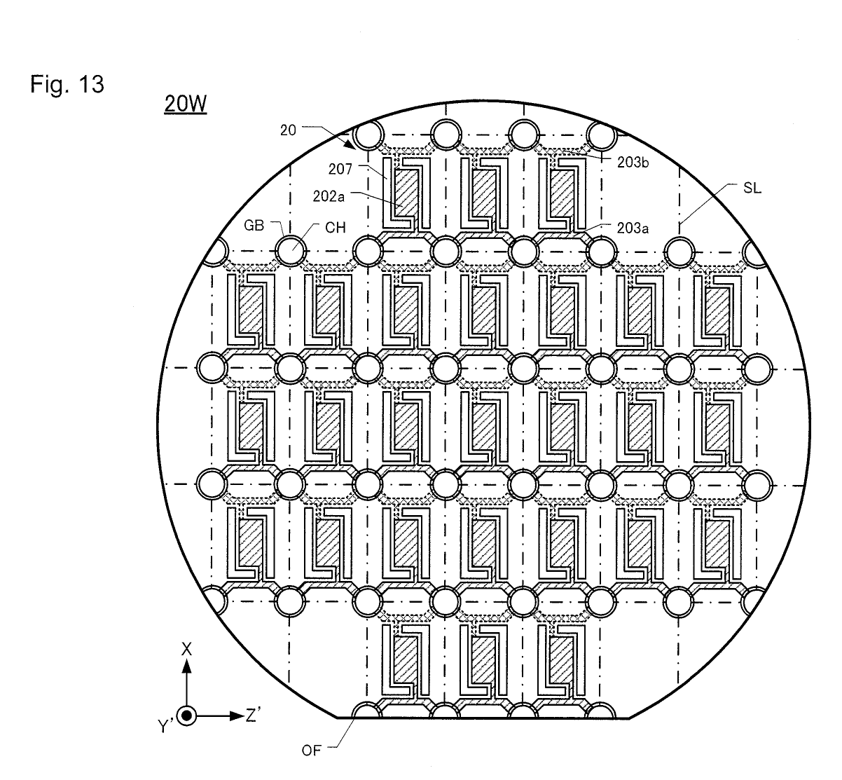

Respective protruding portions 206, formed on the convex portion GB (refer to FIG. 13), are formed about the center in the Y′-axis direction on the quartz-crystal castellations 204a to 204d and protruding outward. Thus, the quartz-crystal castellations 204a to 204d includes a third region 207A having a curved surface from the protruding portions 206 to the respective first surface Me, and a fourth region 207B having a curved surface from the protruding portions 206 to the respective second surface Mi.

The extraction electrode 203b formed on the second surface Mi of the quartz-crystal frame 20 is electrically connected to the base side surface electrode 223b. The quartz-crystal side surface electrodes 205a and 205d are formed on the respective quartz-crystal castellations 204a and 204d, and the quartz-crystal side surface electrodes 205a and 205d are electrically connected to the extraction electrode 203a and respective base side surface electrodes 223a and 223d. Also, it is preferred that the other ends of the respective quartz-crystal side surface electrodes 205a and 205d extend toward the second surface Mi of the quartz-crystal frame 20 and form a connecting pad 205M. The connecting pad 205M is ensured to be electrically connected to the connecting pad 223M formed on the quartz-crystal side surface electrodes 223a and 223d.

The second quartz-crystal vibrating device 200 further comprises a package lid 21, made of a glass or quartz-crystal material, which is bonded to the first surface Me of the quartz-crystal frame 20. On the package lid 21, a first peripheral surface M1 is formed on the periphery of the lid recess 211. As shown in FIG. 11, the package lid 21, the outer frame 208 of the quartz-crystal frame 20 and the package base 22 form a cavity CT for storing the quartz-crystal vibrating piece 201. The cavity CT is filled with an inert-gas or is under a vacuum. The package lid 21, the quartz-crystal frame 20 and the package base 20 are bonded using the sealing material of, for example, low-melting-point glass LG.

An alternating electrical voltage (a potential that regularly alternates positive and negative voltage) is applied to a pair of external electrodes 225a and 225b on the second quartz-crystal vibrating device 200. The external electrode 225a, base side surface electrode 223a, quartz-crystal side surface electrode 205a, extracting electrode 203a and excitation electrode 202a form a same polarity, and the external electrode 225b, base side surface electrode 223b, extracting electrode 203b and excitation electrode 202b form a same polarity. Thus, the quartz-crystal vibrating portion 201 goes into thickness-shear vibration mode.

In this second embodiment, a combination electrode (not shown) can be formed on an outer side of the base castellations 222a to 222d and quartz-crystal castellations 204a to 204b of the second quartz-crystal vibrating device 200. Thus the base side surface electrodes 223a to 223d and the quartz-crystal side surface electrodes 205a to 205d are ensured to be electrically connected.

Furthermore, in the second embodiment, the quartz-crystal frame can be inverted mesa-type, or the package lid and the package base can be a planar plate without a recessed portion.

### <Manufacturing Method of the Second Quartz-Crystal Vibrating Device 200>

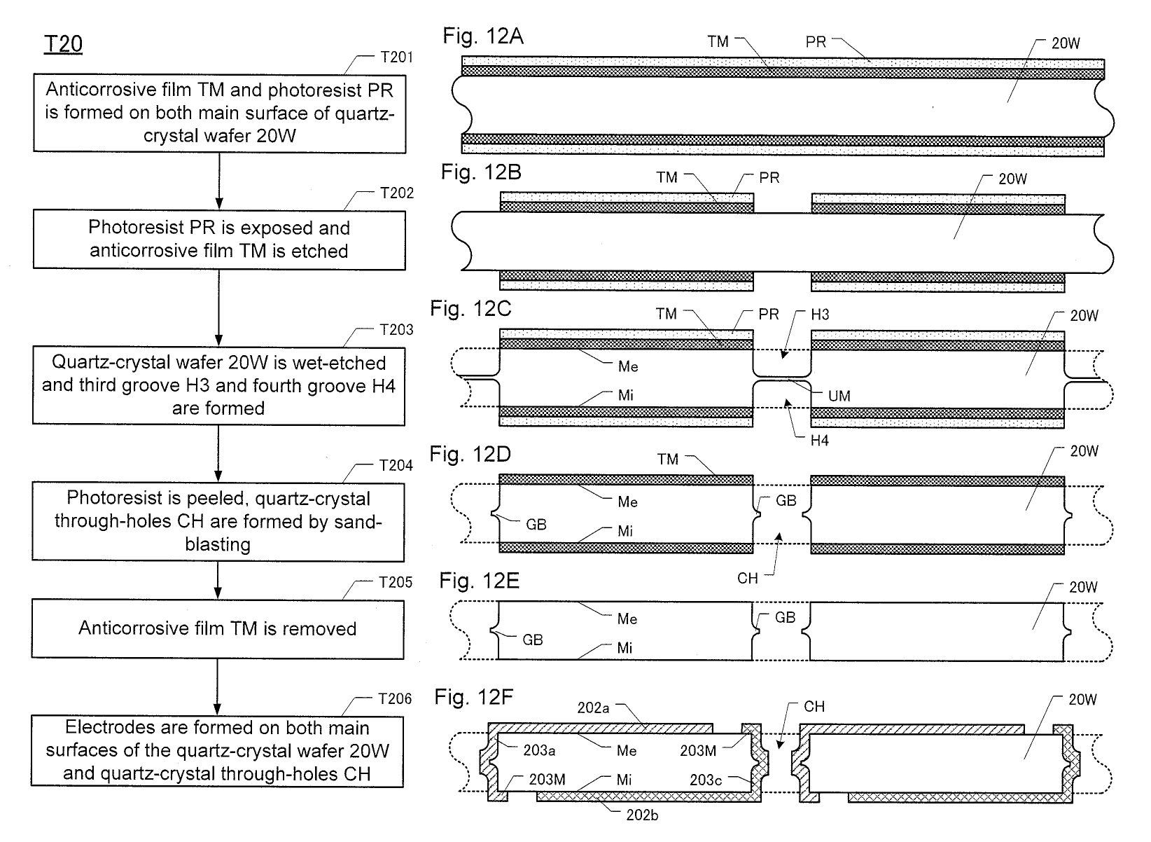

Step T20 for manufacturing a quartz-crystal frame 20 is explained using FIGS. 12 and 13 as references. FIG. 12A to FIG. 12F depicts the results of respective steps T20 of manufacturing a quartz-crystal frame 20, and FIG. 13 is a plan view of the quartz-crystal wafer 20W. FIG. 12A to FIG. 12F are cross-sectional views of the quartz-crystal wafer 20W taken along B-B line, which corresponds to each steps on the flow-chart.

As shown in FIG. 12, manufacturing step T20 of manufacturing the quartz-crystal frame 20 includes steps T201 to T206.

In step T201, as shown in FIG. 12A, an anticorrosive film TM is applied followed by overlaying photoresist PR, on both main surfaces of quartz-crystal wafer 20W, a uniformly thick planar plate of quartz-crystal material. A metal anticorrosive film TM is formed by sputtering or vacuum-deposition. In the second embodiment, a metal layer having a chromium layer and overlaying gold layer is used as an anticorrosive film TM. Next, a photoresist PR is applied uniformly on top of the anticorrosive film TM using methods such as a spin-coating method.

In step T202 (shown in FIG. 12B), using an exposure tool (not shown), the outline patterns of the quartz-crystal frame 20 drawn on the photomask (not shown) are exposed onto the photoresist PR on both main surfaces the quartz-crystal wafer 20W. Here, the outline pattern of the quartz-crystal frame 20 refers to the airspace (gap) portion 207 and the contour of the quartz-crystal castellations 204a to 204d. The denuded photoresist PR is removed by developing. Next, the gold layers of the anticorrosive film exposed from the photoresist PR is etched and removed.

In step T203, as shown in FIG. 12C, both main surfaces of the quartz-crystal wafer 20W, exposed by removal of the anticorrosive film TM and the photoresist PR are wet-etched. Thus, the bottom portions UM are formed on each corner of the quartz-crystal frame 20. Each frame has a third groove H3 and a fourth groove H4, which is grooved by approximately a half of the thickness of the quartz-crystal wafer 20W. Also, although not drawn, grooves are formed on the airspace (gap) portions 207 of the quartz-crystal frame 20, having grooved from the first surface Me and second surface Mi.

In step T204, as shown in FIG. 12D, an abrasive of, for example, sand is applied from the first surface Me or second surface Mi by sand-blasting, with the photoresist PR peeled. Thus, the bottom surface UM of the third groove H3 and the fourth groove H4 are sand-blasted, and form circular quartz-crystal through-holes CH which extend through from the first surface Me to the second surface Mi of the quartz-crystal wafer 20W (refer to FIG. 13). During this step, it is preferred to use masks for sand-blasting, so as to maintain the balance of both main surfaces of the quartz-crystal wafer 20W. When a quartz-crystal through-hole CH is divided in quarters, it forms one quartz-crystal castellation 204a to 204d (refer to FIGS. 10 and 11). Also, the convex portions GB are formed (refer to FIG. 13) at about the center in the thickness direction of the quartz-crystal wafer 20W, which is protruding toward the inner side of the quartz-crystal through-hole CH. When a convex portion GB is divided in quarters, it forms one protruding portion 206a to 206d (refer to FIGS. 10 and 11). Also, although not drawn, the airspace (gap) portions 207 are formed on the quartz-crystal frame 20 simultaneously with the quartz-crystal through-holes CH.

In step T205, as shown in FIG. 12E, the anticorrosive film TM is removed by etching.

In step T206, as shown in FIG. 12F, each electrode is formed on the quartz-crystal through-holes CH, first surface Me and the second surface Mi of the quartz-crystal wafer 20W by following the sputtering and etching method explained in the step S102 of FIG. 3 in the first embodiment. Thus, the quartz-crystal side surface electrodes 205a to 205d are formed on the quartz-crystal through-holes CH. On the first surface Me or the second surface Mi of the quartz-crystal wafer 20W, respective excitation electrodes 202a and 202b, extracting electrodes 203a and 203b, and connecting pad 205M are formed simultaneously (refer to FIGS. 10, 11 and 13).

Next, the package lid 21 of the second quartz-crystal vibrating device 200 is formed by following the same steps as explained in step S11 of FIG. 3 in the first embodiment.

Then, the package base 22 of the second quartz-crystal vibrating device 200 is formed by following the same steps as explained in step S12 of FIG. 3 in the first embodiment. Here, FIG. 14 is a plan view of the base wafer 22W. However, on the base wafer 22W in FIG. 14, the circular base through-holes BH2 are formed on each corner of the package base 22. When a base through-hole BH2 is divided into quarters, it forms one base castellation 222a to 222d (refer to FIGS. 10 and 11). On the second peripheral surface M2 of the base wafer 22W, the low-melting-point glass LG is formed as a sealing material.

In the second embodiment, a step of manufacturing the quartz-crystal frame 20, a step of manufacturing the package lid 21 and a step of manufacturing the package base 22 can be carried out separately or in parallel. Also, the lid wafer 21W, quartz-crystal wafer 20W and base wafer 20W manufactured separately are bonded using the low-melting-point glass LG.

Finally, the bonded lid wafer 21W, quartz-crystal wafer 20W and base wafer 22W are separated into individual pieces. This cutting is performed by cutting along scribe lines SL, denoted by dot-dash lines in FIGS. 13 and 14, using a dicing unit such as a laser beam or a dicing saw. Thus, several hundreds to several thousands of second quartz-crystal piezoelectric vibrating devices 200 are produced.

Although in this manufacturing method of the second quartz-crystal vibrating device 200, the low-melting-point glass is formed on the lid wafer (refer to FIG. 5) and the base wafer 22W before bonding together, it can be formed on the first surface Me or the second surface Mi of the quartz-crystal wafer 20W.

### INDUSTRIAL APPLICABILITY

Multiple representative embodiments are described in detail above. As will be evident to those skilled in the relevant art, the present invention may be changed or modified in various ways within the technical scope of the invention.

For example, the first embodiment can comprise castellations on each corners of the package base, or the second embodiment can comprise castellations on both sides of the package base and quartz-crystal frame in X-axis directions.

Also, in the first and second embodiments, although the base wafer and lid wafer are bonded together using the low-melting-point glass LG, it can be replaced with polyimide resin. Whenever the polyimide resin is used, it can be applied using the screen-printing, or exposed after applying the photosensitive polyimide resin on the entire surface.

Further, in the first and second embodiments, although the external electrodes are formed on the bottom surface of the package base in X-axis direction, the external electrodes can be formed on each corner. In this case, unnecessary external electrodes are used as grounding terminals.

In this specification, although the various embodiments have been described in the context of AT-cut piezoelectric vibrating pieces, it will be understood that the embodiments can be applied with equal facility to tuning-fork type piezoelectric vibrating pieces having a pair of vibrating arms.

Although a quartz-crystal vibrating piece was used in the embodiments described above, other embodiments can be made with equal facility that comprises piezoelectric materials such as lithium tantalite and/or lithium niobate. Further, the present disclosure may be directed to piezoelectric oscillators in which an IC accommodating an oscillating circuit is mounted inside the package on the package base.

What is claimed is:

1. A method for manufacturing a piezoelectric device having a piezoelectric vibrating piece and a package base, the method comprising the steps of:
providing a base wafer of glass or piezoelectric material;
forming an anticorrosive film on a first surface and on a second surface opposing the first surface of the base wafer;
forming a photoresist layer on the anticorrosive film;
exposing the photoresist layer to define the outlines of the package base on the base wafer after the forming step and the photoresist layer is removed for metal-etching,
metal-etching the anticorrosive film corresponding to the through-hole, after the exposing step;
applying an etching solution to the glass or the piezoelectric material and wet-etching the first surface and the second surface of the base wafer until before completely cutting through the glass or the piezoelectric material, after the metal-etching step; and
sand-blasting an abrasive from the second surface side of the base wafer, with the anticorrosive film remaining in place on said second surface.

2. The method for manufacturing the piezoelectric device of claim 1, wherein, the method includes sand-blasting the abrasive from the first surface side of the wafer, with the anticorrosive film remaining in place on said first surface.

3. The method for manufacturing the piezoelectric device of claim 1, further comprising after the sand-blasting method,
a removal step of removing the anticorrosive film; and
a step of forming an external electrode on the second surface for mounting and forming a side surface electrode on respective through-holes, after the removal step.

4. The method for manufacturing the piezoelectric device of claim 2, further comprising after the sand-blasting method,
a removal step of removing the anticorrosive film; and
a step of forming an external electrode on the second surface for mounting and forming a side surface electrode on respective through-holes, after the removal step.

5. The method for manufacturing the piezoelectric device of claim 1, wherein the package base has a rectangular shape with four sides, when viewed from the second surface, and respective through-holes have a circular profile, formed on opposing corners of the package base.

6. The method for manufacturing the piezoelectric device of claim 2, wherein the package base has a rectangular shape with four sides, when viewed from the second surface, and respective through-holes have a circular profile, formed on opposing corners of the package base.

7. The method for manufacturing the piezoelectric device of claim 3, wherein the package base has a rectangular shape with four sides, when viewed from the second surface, and respective through-holes have a circular profile, formed on opposing corners of the package base.

8. The method for manufacturing the piezoelectric device of claim 1, wherein the package base has a rectangular shape with four sides, when viewed from the second surface, and respective through-holes have a rounded-rectangular profile, formed on opposing sides along the package base.

9. The method for manufacturing the piezoelectric device of claim 2, wherein the package base has a rectangular shape with four sides, when viewed from the second surface, and respective through-holes have a rounded-rectangular profile, formed on opposing sides along the package base.

10. The method for manufacturing the piezoelectric device of claim 3, wherein the package base has a rectangular shape with four sides, when viewed from the second surface, and respective through-holes have a rounded-rectangular profile, formed on opposing sides along the package base.

11. A piezoelectric device including a piezoelectric vibrating piece disposed inside a cavity formed by a package lid and a package base, wherein:
the package base comprising a first surface having a pair of external electrodes, a second surface opposing the first surface and a pair of connecting electrodes on the second surface for connecting to the external electrodes through a side surface formed between the first surface and the second surface; and
as viewed in a cross-section, the side surface between the first surface and a second surface comprises a first region defined as a region between the first surface and a center of the side surface, a second region defined as a region between the second surface and the center of the side surface, and a protruding region formed in the center of the side surface and protruding outward.

12. The piezoelectric device of claim 11, wherein the second surface is an uneven surface formed by sand-blasting method.

13. The piezoelectric device of claim 12, wherein the first surface is an uneven surface formed by sand-blasting method.
